(19) United States
(12) Patent Application Publication
(10) Pub. No.: US 2003/0051893 A1
(43) Pub. Date: Mar. 20, 2003

(54) Surface-mounting connector and semiconductor module using the same

(75) Inventors: Tadashi Ichimasa, Kawanishi-shi (JP); Tetsuya Matsuura, Tokyo (JP); Yasushi Kasatani, Tokyo (JP)

Correspondence Address: MCDERMOTT, WILL & EMERY, 600 13th Street, N.W., WASHINGTON, DC, 20005-3096, US

(73) Assignee: Mitsubishi Denki Kabushiki Kaisha

(21) Appl. No.: 10/222,792

(22) Filed: Aug. 19, 2002

(30) Foreign Application Priority Data
Sep. 19, 2001 (JP) 2001-285151

(51) Int. Cl. H02G 3/08; H05K 5/00

(52) U.S. Cl. 174/52.1

(57) ABSTRACT

The present invention has a purpose to provide a surface-mounting connector for electrically connecting with the terminals of the semiconductor module board by pinching thereof, without soldering. The surface-mounting connector includes a supporting member made of insulating material having a first and second surfaces, and a top-surface connecting lead pin and a bottom-surface connecting lead pin. The lead pins are disposed in parallel with a predetermined gap and supported by the supporting member. The top-surface connecting lead pin and the bottom-surface connecting lead pin have one end portions bent in a predetermined direction at different positions away from the first surface of the supporting member.

### CROSS-REFERENCE TO RELATED APPLICATIONS

A related patent application is a commonly assigned Japanese Patent Application No. 2001-285151 filed on Sep. 19, 2001, which is incorporated by reference into the present patent application.

### BACKGROUND OF THE INVENTION

1) Technical Field of the Invention

The present invention relates to a surface-mounting connector and a semiconductor module using the same.

2) Description of Related Arts

Referring to FIGS. 14 to 16, a conventional surface-mounting connector 101 and a semiconductor module 102 using the same will be described hereinafter. As illustrated in FIG. 14, a semiconductor module 102 mounted on a motherboard 103 (also referred to as a “mounting board”), includes, in general, a semiconductor module board 104 made of material such as an epoxy resin, a plurality of semiconductor integrated circuits (ICs) 105 mounted both on a top and bottom surfaces of the semiconductor module board 104, and a surface-mounting connector 101 arranged with the semiconductor module board 104.

As shown in FIGS. 15A to 15C, the conventional surface-mounting connector 101 consists of a plurality of so-called “clip-leads” 106. Each of the clip-leads 106 includes a clip portion 110 formed by bending a electrically conductive stick or band with a C-shape configuration, and a lead portion 112 extending from the clip portion 110. All of the lead portions 112 are together connected with a tie-bar 116 away from the clip portions 112 as shown in FIG. 16A.

In FIG. 15A, each of the clip-leads 106 connected with the tie-bar 116 includes an opening 114 defined within the C-shaped clip portion. The semiconductor module board 104 has peripheral edges, which are inserted and held in the openings of the clip-leads 106. Then, the semiconductor module board 104 sandwiched by the clip portions 110 of the clip-leads 106 are dipped in the solder bath (not shown) so that the each clip-lead 106 is electrically connected with a corresponding terminal (not shown) of the semiconductor module board 104.

Next, in order to electrically isolate the clip-leads 106 from each other, each of the lead portions 112 are cut off (tie-bar cut process) at the position indicated by imaginary line in FIGS. 15B and 16B. To this end, since the clip-leads 106 are first soldered with the corresponding terminal of the semiconductor module board 104 and then cut off, the clip-leads 106 remain connecting with the semiconductor module board 104 even where an external force is afterwards applied thereto (for example, in case where the finger of the operator touches them.)

However, cutting off the clip lead 106 may cause deformation or sag of the lead portions 112, which may, in turn, cause an incomplete contact between the lead portion 112 and the corresponding terminal (not shown) of the motherboard 103. Therefore, once deformation or sag of the lead portions 112 is found, it must be corrected by hand. Such correction is rather troublesome and time-consuming.

Also, as described above, the peripheral edge of the semiconductor module board 104 is inserted into the openings 114 of the C-shaped clip portions 110 so that the clip-leads 106 are supported with the semiconductor module board 104. Therefore, a top and bottom opposing terminals formed on the top and bottom surfaces of the semiconductor module board 104, respectively, are electrically connected to each other through the C-shaped clip portion 110. In other words, the top and bottom terminals which are to be isolated from each other can not be opposed on the top and bottom surfaces of the semiconductor module board 104, respectively. Thus, the top terminal is disposed offset to the bottom terminal so as to avoid electrical connection therebetween via the C-shaped clip portion 110. Therefore, the numbers of the terminals formed on the top and bottom surfaces of the semiconductor module board 104 as well as the semiconductor integrated circuits are restricted.

### SUMMARY OF THE INVENTION

The present invention has a purpose to provide a surface-mounting connector for electrically connecting with the terminals of the semiconductor module board by pinching thereof, without soldering.

Another purpose of the present invention is to provide the surface-mounting connector, of which lead portion does not have to be cut off (tie-bar cut process).

Further another purpose of the present invention is to provide the surface-mounting connector, in which the top and bottom terminals to be isolated from each other can be opposed on the top and bottom surfaces of the semiconductor module board, respectively, so as to reduce the size of the surface-mounting connector.

Further another purpose of the present invention is to provide a semiconductor module incorporating such a surface-mounting connector.

Further another purpose of the present invention is to provide the semiconductor module, which can well resist against more severe thermal-shock test.

In particular, the surface-mounting connector according to the first aspect of the present invention, includes a supporting member made of insulating material having a first and second surfaces, and a top-surface connecting lead pin and a bottom-surface connecting lead pin. The lead pins are disposed in parallel with a predetermined gap and supported by the supporting member. Also, the top-surface connecting lead pin and the bottom-surface connecting lead pin have one end portions bent in a predetermined direction at different positions away from the first surface of the supporting member.

The semiconductor module according to the first aspect of the present invention further includes a semiconductor module board having a top and bottom surfaces, at least one semiconductor integrated circuit electrically connected with the semiconductor module board, a plurality of terminal electrodes formed on the top and bottom surfaces of the semiconductor module board, a supporting member made of insulating material having a first and second surfaces, and a top-surface connecting lead pin and a bottom-surface connecting lead pin. The lead pins are disposed in parallel with a predetermined gap and supported by the supporting member. Also, the top-surface connecting lead pin and the bottom-surface connecting lead pin have one end portions bent in a predetermined direction at different positions away from the first surface of the supporting member. Further, one end portions of the top-surface connecting lead pin and the bottom-surface connecting lead pin cooperatively pinch the terminal electrodes of the semiconductor module board.

Thus, the terminals of the semiconductor module board are pinched by the surface-mounting connector so as to provide an electrical connection between the surface-mounting connector and the terminals of the semiconductor module board. This eliminates the soldering process and facilitates the assembling the surface-mounting connector and the semiconductor module board for manufacturing the semiconductor module. Also, the lead pins have no need to be cut off, so that no deformation and sag of the lead pins are formed. In addition, the top-surface connecting lead pin and bottom-surface connecting lead pin connect with the terminals opposingly disposed on the top and bottom surface of the semiconductor module board in an electrically isolated manner. Therefore, the size of the surface-mounting connector required for connecting with a predetermined number of terminals can be reduced in half. To this end, the semiconductor module of the present invention can substantially be downsized.

According to the surface-mounting connector of the present invention, the top-surface connecting lead pin and the bottom-surface connecting lead pin have other end portions bent in a reverse direction opposing to the predetermined direction and in the predetermined direction, respectively, at the same positions away from the second surface of the supporting member. Thus, this facilitates assembling the semiconductor module with a surface-mounting board.

Also, the surface-mounting connector of the present invention further includes a plurality of the top-surface connecting lead pins and the bottom-surface connecting lead pins. Those lead pins are aligned in an alignment direction perpendicular to the predetermined direction and supported by the supporting member. Thus, a plurality of terminal electrodes can be formed on the top and bottom surfaces of the semiconductor module board.

Further, in the surface-mounting connector according to the second aspect of the present invention, one end portion of the bottom-surface connecting lead pin contacts with the first surface of the supporting member, and the top-surface connecting lead pin has a contact portion bent for contacting with the second surface of the supporting member. Thus, one end portion of the bottom-surface connecting lead pin underpins the bottom-surface connecting lead pin, and the contact portion underpins the top-surface connecting lead pin, thereby preventing them from sliding relative to the supporting member. Also, the resilient force of the top-surface connecting lead pin secures electrical connection between connector element and the semiconductor module board, thereby realizing a more reliable semiconductor module.

Also, in the surface-mounting connector according to the present invention, one end portion of the bottom-surface connecting lead pin contacts with the first surface of the supporting member. Also, the top-surface connecting lead pin has an extension portion contacting with the second surface of the supporting member.

Further, in the surface-mounting connector according to the third aspect of the present invention, the supporting member has a boss portion formed on the first surface thereof.

In the semiconductor module according to the third aspect of the present invention, the semiconductor module board has a recess portion. Correspondingly, the supporting member has a boss portion formed on the first surface thereof. The boss portion have a configuration conforming to that of the recess portion of the supporting member.

Thus, the lead pins are aligned with the terminals in a precise manner, with the use of the boss portion and the cut-out portion as alignment guides. This secures accurate alignment between the surface-mounting connector and the terminals for electrical connection. Also, once the surface-mounting connector and the semiconductor module board are connected, the boss portion and the cut-out portion limit the relative movement so as to realize a robust semiconductor module against an external force.

Also, in the surface-mounting connector according to the present invention, the supporting member has at least two boss portions formed on the first surface thereof.

In addition, in the semiconductor module according to the present invention, the semiconductor module board and the supporting member have at least two recess portions and boss portions, respectively.

Further, in the surface-mounting connector according to the fourth aspect of the present invention, one end portions of the top-surface connecting lead pin and the bottom-surface connecting lead pin cooperatively pinch a semiconductor module board, and other end portions of the top-surface connecting lead pin and the bottom-surface connecting lead pin are connected with a mounting board.

Also, the top-surface connecting lead pin and the bottom-surface connecting lead pin have lengths designed such that a distance between the semiconductor module board and the mounting board is 2.0 mm or more.

Also, in the surface-mounting connector according to the present invention, the top-surface connecting lead pin and the bottom-surface connecting lead pin have bent portions between the supporting member and the other end portions.

Further scope of applicability of the present invention will become apparent from the detailed description given hereinafter. However it should be understood that the detailed description and specific examples, while indicating preferred embodiments of the invention, are given by way of illustration only, since various changes and modifications within the sprit and scope of the invention will become apparent to those skilled in the art from this detailed description.

### BRIEF DESCRIPTION OF THE DRAWINGS

The present invention will more fully be understood from the detailed description given hereinafter and accompanying drawings which are given by way of illustration only, and thus are not limitative of the present invention and wherein,

FIG. 1 is a perspective view of a surface-mounting connector and a semiconductor module using the connector according to Embodiment 1 of the present invention, and as well as of a motherboard;

FIG. 2 is a partial enlarged perspective view of the surface-mounting connector and the semiconductor module using the connector according to Embodiment 1;

FIG. 3 is a cross sectional view of the surface-mounting connector taken along a line of III-III of FIG. 1;

FIG. 4 is a partial top view of the surface-mounting connector and the semiconductor module using the connector according to Embodiment 1;

FIG. 5 is a partial side view of the surface-mounting connector and the semiconductor module using the connector according to Embodiment 1;

FIG. 6 is a cross sectional view, similar to FIG. 3, of the surface-mounting connector according to Embodiment 2 of the present invention;

FIG. 7 is a cross sectional view, similar to FIG. 3, of the surface-mounting connector according to an alternative of Embodiment 2;

FIG. 8 is a partial enlarged perspective view of the surface-mounting connector and the semiconductor module using the connector according to Embodiment 3 of the present invention;

FIG. 9 is a partial plane view, similar to FIG. 4, of the surface-mounting connector and the semiconductor module using the connector according to Embodiment 3;

FIG. 10 is a partial top view, similar to FIG. 5, of the surface-mounting connector and the semiconductor module using the connector according to Embodiment 3;

FIG. 11 is a cross sectional view, similar to FIG. 3, of the surface-mounting connector according to Embodiment 4 of the present invention;

FIG. 12 is a cross sectional view of the semiconductor module using the surface-mounting connector according to Embodiment 1, which is mounted on a motherboard;

FIG. 13 is a cross sectional view, similar to FIG. 3, of the surface-mounting connector according to an alternative of Embodiment 4;

FIG. 14 is a perspective view of a conventional surface-mounting connector and a semiconductor module using the connector, which is mounted on a motherboard;

FIGS. 15A to 15C are side views of the conventional surface-mounting connector and the semiconductor module using the connector;

FIGS. 16A and 16B are top views of the conventional surface-mounting connector and the semiconductor module using the connector.

### DETAILED DESCRIPTION OF THE PREFERRED EMBODIMENTS

Referring to the attached drawings, the details of embodiments according to the present invention will be described hereinafter. In those descriptions, although the terminology indicating the directions (for example, “upper”, “lower”, “right”, and “left”) are conveniently used just for clear understandings, it should not be interpreted that those terminology limit the scope of the present invention.

Embodiment 1.

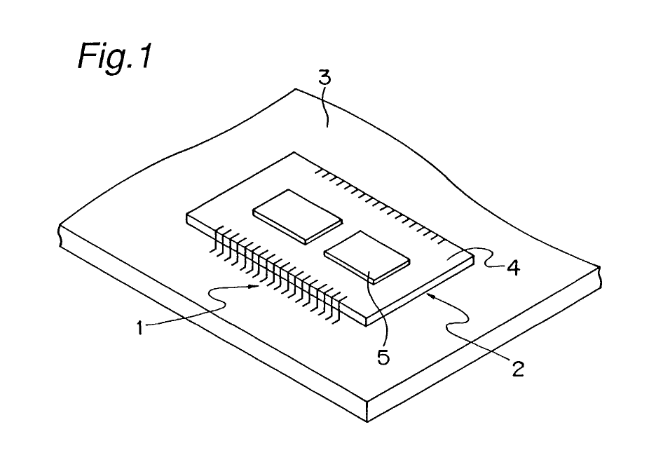

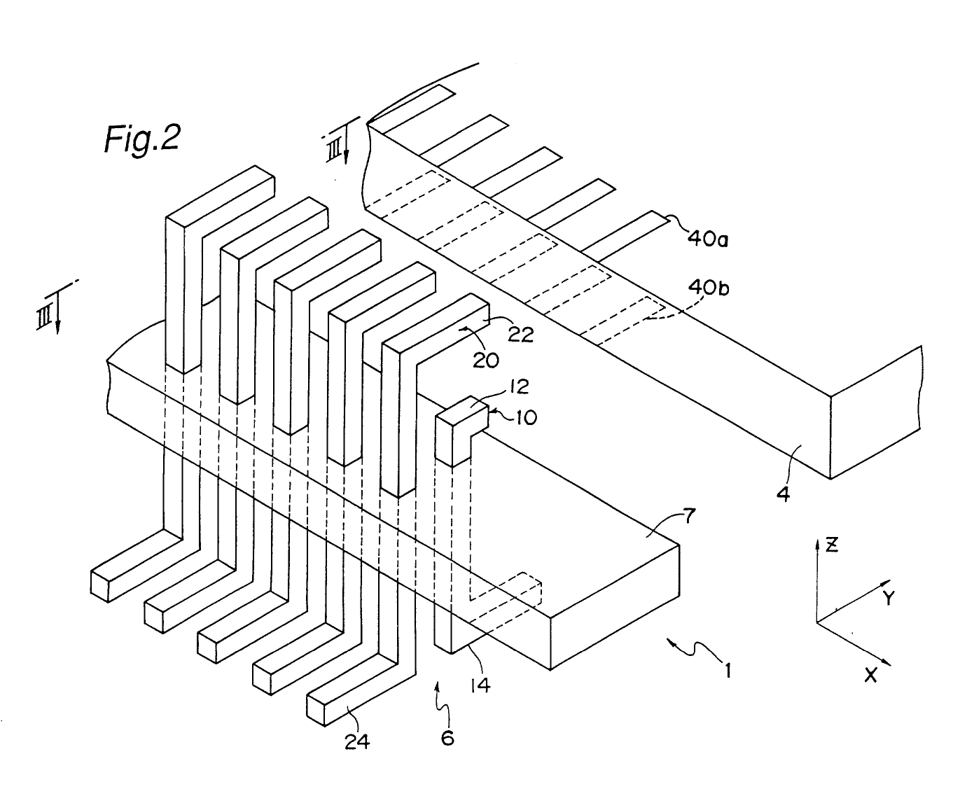

With reference to FIGS. 1 to 5, a surface-mounting connector 1 of Embodiment 1 according to the present invention and a semiconductor module 2 using the surface-mounting connector 1 will be described hereinafter. In FIG. 1, the semiconductor module 2 of the present invention, which is to be mounted on a motherboard 3 (also referred to as a “mounting board”) includes, in general, a semiconductor module board 4 made of material such as an epoxy resin, a plurality of semiconductor integrated circuits (ICs) 5 mounted both on a top and bottom surfaces of the semiconductor module board 4, and a surface-mounting connector 1 provided with the semiconductor module board 4. The semiconductor module board 4 includes a plurality of top and bottom terminal electrodes 40a, 40b formed on a top and bottom surfaces 36, 38 of the semiconductor module board 4, respectively, with a predetermined distance along the X-direction illustrated in FIG. 2.

As shown in FIG. 2, the surface-mounting connector 1 includes, in general, a plurality of connector elements 6 made of conductive material such as solder-coated phosphor bronze, and a supporting member 7 made of non-conductive (insulating) and substantially solid material such as epoxy resin. Each of the connector elements 6, which will be described in more detail later, includes an inner lead pin 10 (also referred to as a “bottom-surface connecting lead pin”) which is closer to the semiconductor module board 4, and an outer lead pin 20 (also referred to as a “top-surface connecting lead pin”) which is away from the semiconductor module board 4.

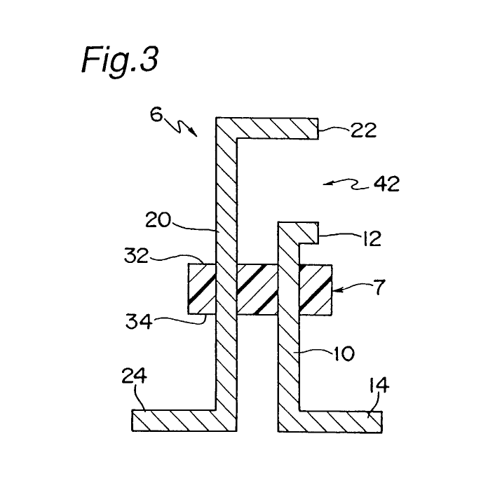

The supporting member 7 together supports a plurality of the inner and outer lead pins 10, 20 so that the inner and outer lead pins 10, 20 are spaced away from each other with a predetermined distance along the X-direction and the Y-direction illustrated in FIG. 2. (Note that only one inner lead pin 10 is shown in FIG. 2 for clarity.) The supporting member 7 may be formed by injecting resin into a mold (not shown), in which the inner and outer lead pins 10, 20 are set in advance. Alternatively, the surface-mounting connector 1 may be formed in such a way that the inner and outer lead pins 10, 20 are inserted into a plurality of through-holes (not shown) provided on the supporting member 7. Also, the supporting member 7 generally extends along the X-direction of FIG. 2, and as shown in FIG. 3, includes a rectilinear cross section and an upper surface 32 (also referred to as a “first surface”) and a lower surface 34 (also referred to as a “second surface”) in the Z-direction of FIG. 2.

Meanwhile, the inner and outer lead pins 10, 20 extend parallel to each other along the Z-direction of FIG. 2. As above, in the Z-direction, each of the inner and outer lead pins 10, 20 are spaced leaving the same distance as that of the terminals 40a, 40b so as to electrically connect with the corresponding terminals 40a, 40b.

The inner and outer lead pins 10, 20 include upper end portions 12, 22 bent substantially 90 degrees towards the Y-direction of FIG. 2 (right direction of FIG. 3) at the different Z-positions away from the upper surface 32 of the supporting member 7. Thus, the upper end portions 12, 22 of the inner and outer lead pins 10, 20, in cooperation with each other, define a pinch member 42 for pinching the semiconductor module board 4. The upper end portions 12, 22 of the inner and outer lead pins 10, 20 have a gap in the pinch member 42. Preferably the gap is the same as or slightly less than the thickness of the semiconductor module board 4. This ensures the terminals 40a, 40b to be secured by expanded inner and outer lead pins 10, 20 in a more reliable manner, when the semiconductor module board 4 is inserted into the pinch portion 42, because the inner and outer lead pins 10, 20 made of conductive material such as metal, are resilient. Therefore, the upper end portions 12, 22 of the inner and outer lead pins 10, 20 provide electrical connection with the terminals 40a, 40b by tightly pinching thereof without soldering.

Also, the inner and outer lead pins 10, 20 include lower end portions 14, 24 bent substantially 90 degrees towards the opposing direction in the Y-Z plane of FIG. 2 (right and left direction of FIG. 3) at the same Z-positions away from the lower surface 34 of the supporting member 7. Thus, after the semiconductor module 2 is completed, the lower end portions 14, 24 are soldered on the motherboard 3.

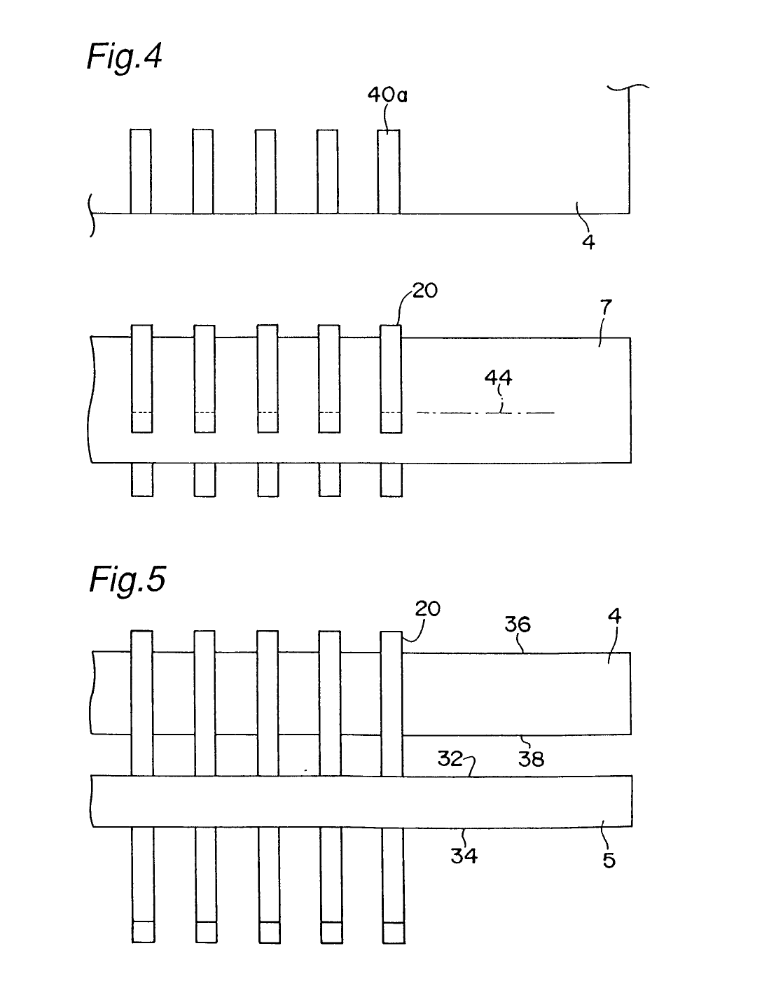

As described above, the semiconductor module board 4 is inserted into the pinch portion 42 of the surface-mounting connector 1 along the X-direction of FIG. 2, up to the position indicated by imaginary line 44 of FIG. 4, i.e., until the semiconductor module board 4 contacts with the outer lead pin 20. Therefore, the semiconductor module 2 of the present invention is manufactured. Thus, the soldering process can be eliminated in manufacturing the semiconductor module 2. Also, contrary to the conventional clip-lead as described above, since the surface-mounting connector 1 of the present invention has no tie-bar, which would otherwise requires the tie-bar cutting process. Thus, this excludes the possibility of deformation or sag of the inner and outer lead pin 10, 20, thereby avoiding electrical failure when the lower end portions 14, 24 are soldered on the motherboard 3. Furthermore, since the inner and outer lead pins 10, 20 are electrically isolated from each other, the terminals 40a, 40b opposingly disposed on the top and bottom surface of the semiconductor module board 4 can separately be connected with the motherboard 3 through the inner and outer lead pins 10, 20, respectively. Therefore, the size of the surface-mounting connector 1 of the present invention required for connecting with a predetermined number of terminals can be reduced to half, comparing with the conventional clip-leads, thereby realizing a compact surface-mounting connector 1.

Embodiment 2.

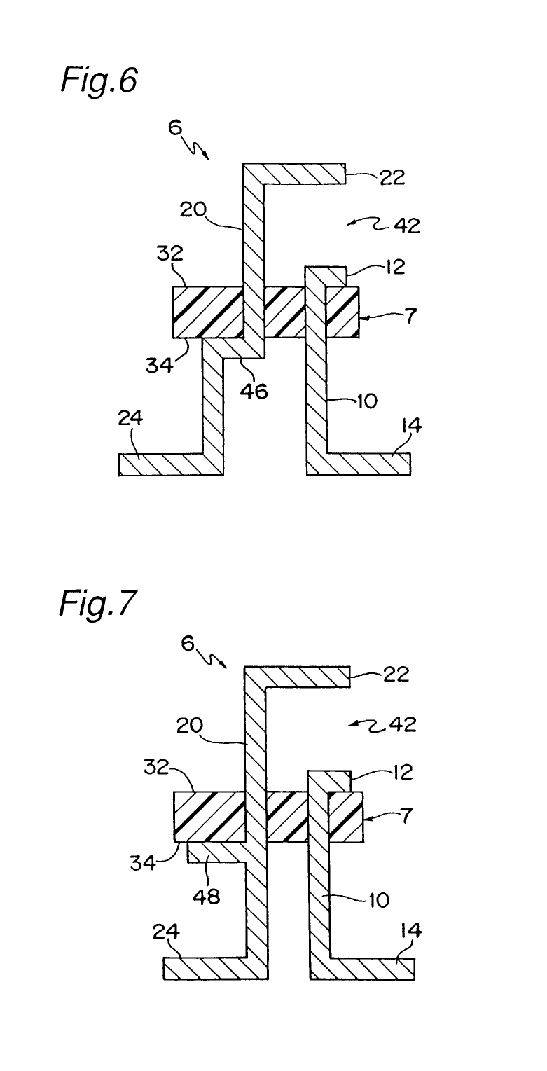

Referring to FIGS. 6 and 7, a surface-mounting connector 1 of Embodiment 2 according to the present invention will be described hereinafter. As can be seen in FIG. 6, the upper end portion 12 of the inner lead pin 10 contacts with the upper surface 32 of the supporting member 7 without leaving any gap therebetween. On the other hand, the outer lead pin 20 has a contact portion 46 bent substantially 90 degrees so that the contact portion 46 contacts with the lower surface of the supporting member 7. Other structures of the connector element 6 of Embodiment 2 are similar to those of Embodiment 1, thus, no duplicate description will be eliminated.

As above, the upper end portion 12 of the inner lead pin 10 so constructed is supported directly on the upper surface 32 of the supporting member 7. Thus, even if the inner lead pin 10 is pressed down (to the motherboard 3) when the semiconductor module 4 is inserted into the pinch portion 42, the inner lead pin 10 can be sustained in the supporting member 7. Therefore, the upper end portion 12 underpins the inner lead pin 10 thereby preventing it from sliding downwardly. Similarly, the outer lead pin 20 as described has the contact portion 46 supported directly on the lower surface 34 of the supporting member 7. Thus, even if the outer lead pin 20 is pulled up (to the semiconductor module board 4) when the semiconductor module 4 is inserted into the pinch portion 42, the outer lead pin 20 can be sustained in the supporting member 7. Therefore, the contact portion 46 underpins the outer lead pin 20 thereby preventing it from sliding upwardly. As the result, the robust surface-mounting connector 1 reinforcing the supporting strength between the inner and out lead pins 10, 20 and supporting member 7 can be realized. In addition, the inner and outer lead pins 10, 20 of Embodiment 2 are secured with the supporting member 7 in a more reliable manner preventing them from sliding relative to the supporting member 7, thus, the resilient force of the outer lead pin 20 is more efficiently applied to the terminal electrodes 40a, 40b. Therefore, this substantially improves reliability for electrical connection between the connector element 6 and the semiconductor module board 4.

Alternatively, as illustrated in FIG. 7, the outer lead pin 20 may have an extended portion 48 that contacts with the lower surface of the supporting member 7, instead of the contact portion 46. Since the other structures are similar to that of the outer lead pin of Embodiment 2, the details will not be described furthermore. Similarly to Embodiment 2, the outer lead pin 20 so constructed can be sustained in the supporting member 7, even if the outer lead pin 20 is pulled up (to the semiconductor module board 4) when the semiconductor module 4 is inserted into the pinch portion 42. Thus, the contact portion 46 underpins the outer lead pin 20 thereby preventing it from sliding upwardly, so that the outer lead pin 20 pinches the terminal electrodes 40a, 40b with the resilient force in a more efficient manner. This provides more reliable connection between the connector element 6 and the semiconductor module board 4.

Embodiment 3

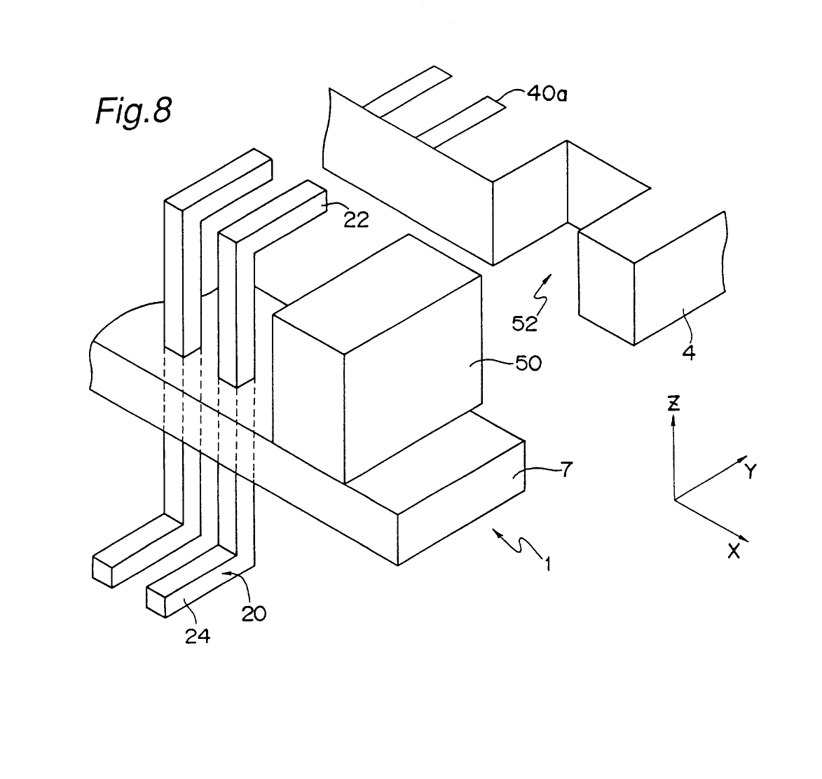

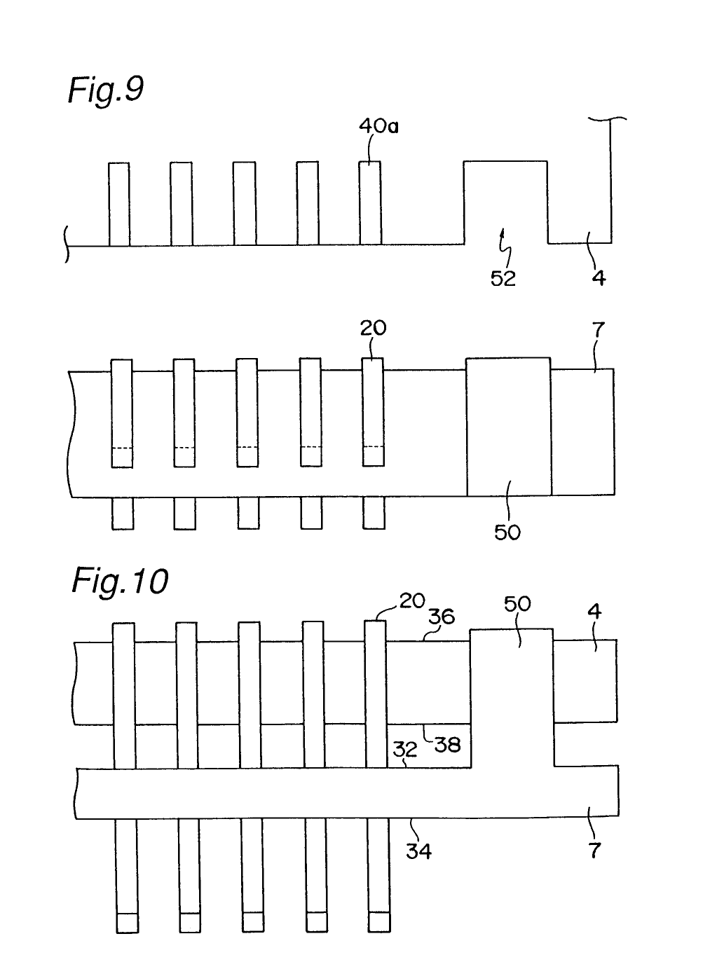

Referring to FIGS. 8 to 10, a surface-mounting connector 1 of Embodiment 3 according to the present invention and a semiconductor module 2 using the surface-mounting connector 1 will be described hereinafter. In FIG. 8, the inner lead pin 10 and the terminal electrodes 40b formed on the bottom surface 38 of the semiconductor module board 4 are eliminated for clarity. In the surface-mounting connector 1 of Embodiment 3, the supporting member 7 extending along the X-direction of FIG. 8 includes a boss portion 50 at one end, which is protruded from the upper portion 32 upwardly along the Z-direction of FIG. 8. The boss portion is preferably formed together of the same epoxy resin. As shown in FIGS. 9 and 10, the boss portion 50 has rectilinear configuration when viewed both from the top and the side. Meanwhile, the semiconductor module board 4 of Embodiment 3 has a cut-out portion (recess portion) 52 with a rectilinear configuration conforming to that of the boss portion 50 so as to receive the boss portion 50. Also, the distance along the X-direction of FIG. 8 between the cut-out portion 52 and the terminals 40a, 40b is the same as that between the boss portion 50 and the connector elements 6. The other structures except those indicated above are similar to those of Embodiment 1, no further description will be made in detail.

As described above, the semiconductor module board 4 is inserted into the pinch portion 42 of the surface-mounting connector 1, so that the boss portion 50 formed on the supporting member 7 is received in the cutout portion 52 of the semiconductor module board 4. Thus, the inner and outer lead pins 10, 20 are aligned with the terminals 40a, 40b along the X-direction of FIG. 8 in a precise manner, with the use of the boss portion 50 and the cut-out portion 52 as alignment guides. This secures an accurate alignment between the surface-mounting connector 1 and the terminals 40a, 40b of the semiconductor module board 4 for electrical connection. Also, once the surface-mounting connector 1 and the semiconductor module board 4 are connected, the boss portion 50 and the cut-out portion 52 perform another function for limiting the movement thereof along the X-direction of FIG. 8, so as to realize a robust semiconductor module 2 bearing an external force such as oscillation.

More preferably, the supporting member 7 and the semiconductor module board 4 include two of the boss portions 50 and cut-out portions 52 formed on their opposite ends in the X-direction, respectively, rather than only one. This provides an even more reliable semiconductor module 2.

Embodiment 4

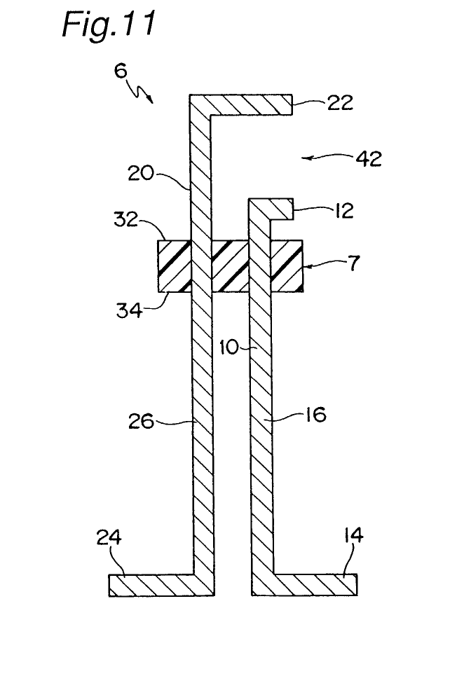

Referring to FIGS. 11 to 13, a surface-mounting connector 1 of Embodiment 4 according to the present invention will be described hereinafter. In FIG. 11, middle portions 16, 26 of the inner and outer lead pins 10, 20 are defined between the supporting member 7 and the lower end portions 14, 24. According to Embodiment 4, the middle portions 16, 26 of the inner and outer lead pins 10, 20 are substantially longer than those of Embodiment 1. In particular, while the distance between the motherboard 3 and the semiconductor module board 4 of Embodiment 1 is approximately 1.0 mm, the middle portions 16, 26 of Embodiment 4 are designed so that the distance between the motherboard 3 and the semiconductor module board 4 is approximately 2.0 mm. More preferably, the middle portions 16, 26 are designed so that the distance between the motherboard 3 and the semiconductor module board 4 is 3.0 mm. As described herein, a more robust and reliable semiconductor module 2 with the longer middle portions 16, 26 can be obtained, satisfactorily resisting against a severer thermal shock (a heat cycle evaluation test).

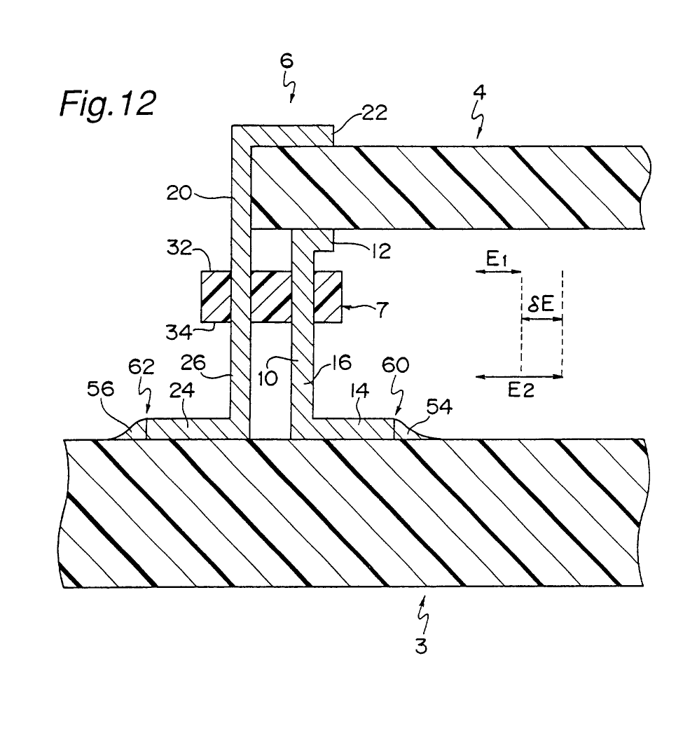

With reference to FIG. 12, the reason why the semiconductor module 2 with the longer middle portions 16, 26 can be more reliable will be described hereinafter. In FIG. 12, the semiconductor module 2 and the motherboard 3 are soldered, for example, in a solder reflow process, so that the lower end portions 14, 24 of the inner and outer lead pins 10, 20 are connected with the corresponding lands (not shown) of the motherboard 3 via soldering 54, 56, respectively. The motherboard 3 and the semiconductor module board 4 have different thermal expansion coefficients, depending upon compound materials and geometric configurations. In other words, the motherboard 3 and the semiconductor module board 4 have different linear expansion degrees in the lateral direction in FIG. 12. In general, the linear expansion degree E1 of the semiconductor module board 4 is smaller than the linear expansion degree E2 of the motherboard 3, having a difference (δE=E2−E1) between the linear expansion degrees E1 and E2. Thus, as illustrated in FIG. 12, at the high temperature during the heat cycle evaluation test, the motherboard 3 expands more than the semiconductor module board 4 so that the stress is applied to the left solder 56 towards the left direction. Also, at the low temperature during the heat cycle evaluation test, the motherboard 3 shrinks more than the semiconductor module board 4 so that the stress is applied to the right solder 54 towards the right direction. Thus, the stresses are applied to the solders 54, 56 so that the solders 54, 56 are pulled away from the lower end portions 14, 24 of the inner and outer lead pins 10, 20. Since the interface portions 60, 62 between the lower end portions 14, 24 and the solders 54, 56, repsectively, are relatively weak, the lateral stress repeatedly applied with the solders 54, 56 easily causes soldering cracks at the interface portions 60, 62, leading an electrical failure such as an open circuit.

Nevertheless, the middle portions 16, 26 of the inner and outer lead pins 10, 20 of Embodiment 4 are resilient and long enough to curve laterally for absorbing the lateral stresses due to the different thermal expansion coefficients under the thermal shock. In other words, the longer middle portions 16, 26 can absorb the lateral stresses more satisfactorily. Therefore, the longer distance between the motherboard 3 and the semiconductor module board 4 absorbs greater lateral stresses, then the semiconductor module 2 of Embodiment 4 can be more robust and reliable, resisting against the severer thermal shock.

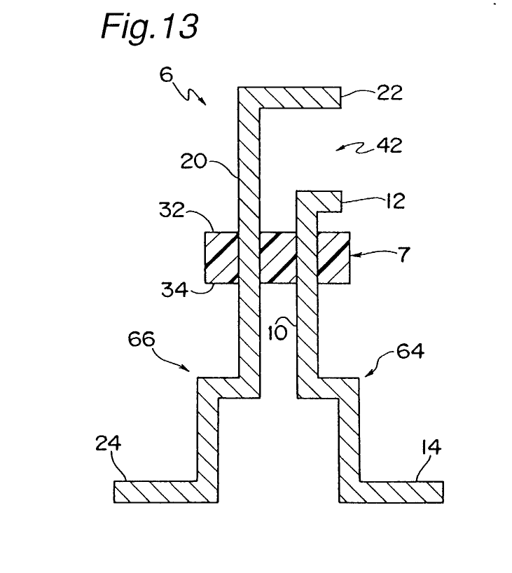

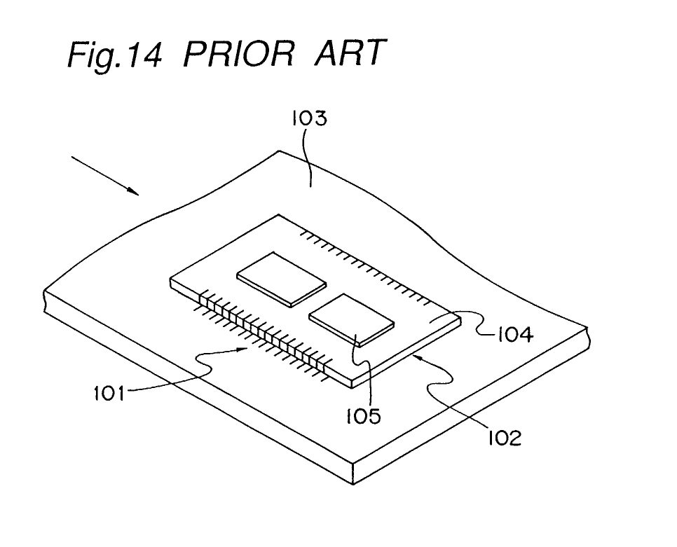

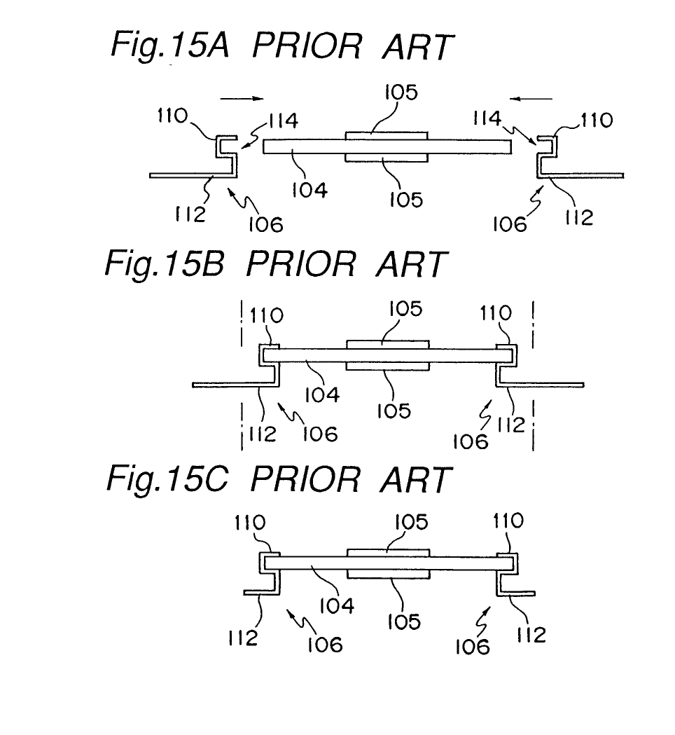

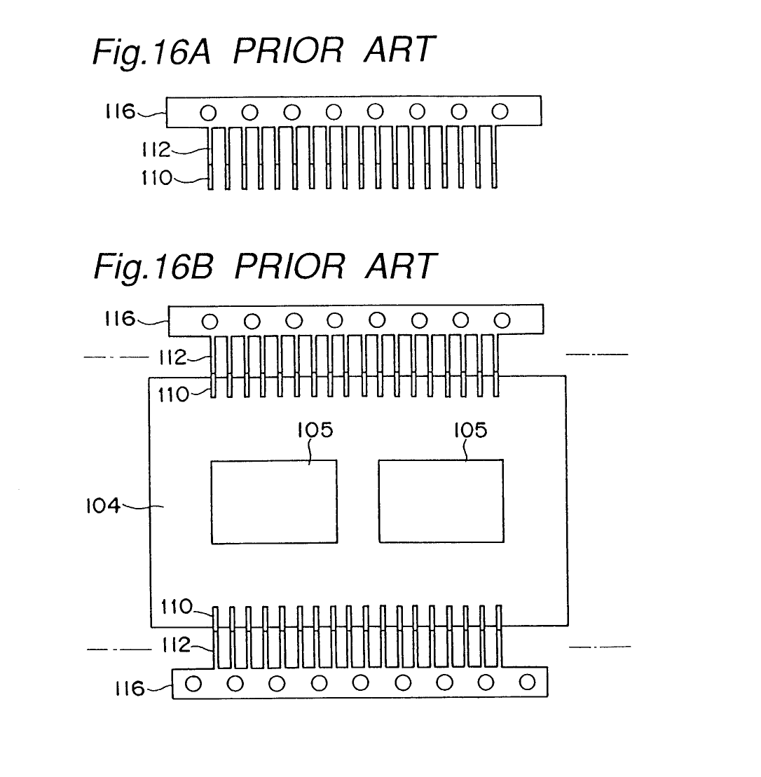

Alternatively, as illustrated in FIG. 13, the middle portions 16, 26 of the inner and outer lead pins 10, 20 may have bent or substantially right angled portions 64, 66, respectively. In this case, the middle portions 16, 26 are designed to have the length similar to that of the Embodiment 4. Thus, the middle portions 16, 26 relive the lateral heat stress so that the semiconductor module 2 withstands the severer thermal shock as well as one of Embodiment 4. In addition, the bent portions 64, 66 reduce the distance between the motherboard 3 and the semiconductor module board 4, maintaining the advantage to relieve the lateral stress as described above. In other words, the reliable semiconductor module 2 can be obtained, reducing the distance between the motherboard 3 and the semiconductor module board 4. Also, as is clear to those skilled in the art, it should be noted that either one of the inner and outer lead pins 10, 20 may have the bent portion to achieve the similar advantages as described above.

What is claimed is:

1. A surface-mounting connector, comprising:
a supporting member made of insulating material having a first and second surfaces; and
a top-surface connecting lead pin and a bottom-surface connecting lead pin, said lead pins disposed in parallel with a predetermined gap and supported by said supporting member;
wherein said top-surface connecting lead pin and said bottom-surface connecting lead pin have one end portions bent in a predetermined direction at different positions away from the first surface of said supporting member.

2. The surface-mounting connector according to claim 1,
wherein said top-surface connecting lead pin and said bottom-surface connecting lead pin have other end portions bent in a reverse direction opposing to the predetermined direction and in the predetermined direction, respectively, at the same positions away from the second surface of said supporting member.

3. The surface-mounting connector according to claim 1, further comprising:
a plurality of said top-surface connecting lead pins and said bottom-surface connecting lead pins, aligned in an alignment direction perpendicular to the predetermined direction and supported by said supporting member.

4. The surface-mounting connector according to claim 1,
wherein one end portion of said bottom-surface connecting lead pin contacts with the first surface of said supporting member, and
wherein said top-surface connecting lead pin has a contact portion bent for contacting with the second surface of said supporting member.

5. The surface-mounting connector according to claim 1,
wherein one end portion of said bottom-surface connecting lead pin contacts with the first surface of said supporting member, and
wherein said top-surface connecting lead pin has an extension portion contacting with the second surface of said supporting member.

6. The surface-mounting connector according to claim 1,
wherein said supporting member has a boss portion formed on the first surface thereof.

7. The surface-mounting connector according to claim 6,
wherein said supporting member has at least two boss portions formed on the first surface thereof.

8. The surface-mounting connector according to claim 2,
wherein one end portions of said top-surface connecting lead pin and said bottom-surface connecting lead pin cooperatively pinch a semiconductor module board,
wherein other end portions of said top-surface connecting lead pin and said bottom-surface connecting lead pin are connected with a mounting board, and
wherein said top-surface connecting lead pin and said bottom-surface connecting lead pin have lengths designed such that a distance between the semiconductor module board and the mounting board is 2.0 mm or more.

9. The surface-mounting connector according to claim 2,
wherein said top-surface connecting lead pin and said bottom-surface connecting lead pin have bent portions between said supporting member and the other end portions.

10. A semiconductor module, comprising:
a semiconductor module board having a top and bottom surfaces;
at least one semiconductor integrated circuit electrically connected with said semiconductor module board;
a plurality of terminal electrodes formed on the top and bottom surfaces of the semiconductor module board;
a supporting member made of insulating material having a first and second surfaces; and
a top-surface connecting lead pin and a bottom-surface connecting lead pin, said lead pins disposed in parallel with a predetermined gap and supported by said supporting member;
wherein said top-surface connecting lead pin and said bottom-surface connecting lead pin have one end portions bent in a predetermined direction at different positions away from the first surface of said supporting member, and
wherein one end portions of said top-surface connecting lead pin and said bottom-surface connecting lead pin cooperatively pinch the terminal electrodes of said semiconductor module board.

11. The semiconductor module according to claim 10,
wherein said top-surface connecting lead pin and said bottom-surface connecting lead pin have other end portions bent in a reverse direction opposing to the predetermined direction and in the predetermined direction, respectively, at the same positions away from the second surface of said supporting member.

12. The semiconductor module according to claim 10, further comprising:
a plurality of said top-surface connecting lead pins and said bottom-surface connecting lead pins, aligned in an alignment direction perpendicular to the predetermined direction and supported by said supporting member.

13. The semiconductor module according to claim 10,
wherein one end portion of said bottom-surface connecting lead pin contacts with the first surface of said supporting member, and
wherein said top-surface connecting lead pin has a contact portion bent for contacting with the second surface of said supporting member.

14. The semiconductor module according to claim 10,
wherein one end portion of said bottom-surface connecting lead pin contacts with the first surface of said supporting member, and
wherein said top-surface connecting lead pin has an extension portion contacting with the second surface of said supporting member.

15. The semiconductor module according to claim 10,
wherein said semiconductor module board has a recess portion, and
wherein said supporting member has a boss portion formed on the first surface thereof, the boss portion having a configuration conforming to that of the recess portion of said supporting member.

16. The semiconductor module according to claim 15,
wherein said semiconductor module board and said supporting member have at least two recess portions and boss portions, respectively.

17. The semiconductor module according to claim 11,
wherein other end portions of said top-surface connecting lead pin and said bottom-surface connecting lead pin are connected with a mounting board, and
wherein said top-surface connecting lead pin and said bottom-surface connecting lead pin have lengths designed such that a distance between the semiconductor module board and the mounting board is 2.0 mm or more.

18. The semiconductor module according to claim 18,
wherein said top-surface connecting lead pin and said bottom-surface connecting lead pin have bent portions between said supporting member and the other end portions.
